(19) United States
(12) Patent Application Publication
(10) Pub. No.: US 2018/0198050 A1
(43) Pub. Date: Jul. 12, 2018

(54) ENERGY HARVESTING DEVICE

(71) Applicants: Swansea University, Swansea (GB); Soochow University, Jiangsu (CN)

(72) Inventors: Lijie Li, Swansea (GB); Jianhua Jiang, Suzhou (CN)

(21) Appl. No.: 15/403,618

(22) Filed: Jan. 11, 2017

(51) Int. Cl. H01L 35/34; H01L 35/32

(52) U.S. Cl. CPC H01L 35/34; H01L 35/32

(57) ABSTRACT

An energy harvesting device uses quantum dot layers or nanowires to generate an electrical potential between first and second electrodes. The device enables thermal energy generated from a heat source to be used in a battery to power a device.

### FIELD OF THE INVENTION

This invention relates generally to an energy harvesting device and a battery comprising an energy harvesting device.

### BACKGROUND OF THE INVENTION

Thermoelectric energy generation have been extensively studied in recent years as they offer a way in which heat energy, such as that generated in power generation, can be converted into electrical power.

However, realising the full potential of devices designed to implement thermoelectric energy generation has been limited by technical constraints related to the materials involved.

Aspects and embodiments were conceived with the foregoing in mind.

### SUMMARY OF THE INVENTION

A device in accordance with the aspect may be used in a circuit used to power a device such as, for example, a mobile computing device or a sensor.

Viewed from a first aspect, there is provided an energy harvesting device comprising a first electrode and a second electrode spaced apart relative to each other to define a cavity and a plurality of quantum dot layers disposed within the cavity.

Each of the plurality of quantum dot layers may have an energy level which is higher than the energy level of the preceding quantum dot layer.

Each of the quantum dot layers may comprise a plurality of quantum dots uniformly distributed in a colloidal substance.

The number of quantum dot layers may be between 20 and 40.

The radius of the quantum dot may be inversely proportional to the energy level of the quantum dot.

The spacing between the quantum dot layers may be less than the localisation length of the quantum dot layer.

Power management circuitry may be coupled to one of the first or second electrodes.

A heat source may be coupled to the device to generate the emission of electrons from one of the first or second electrodes.

The power management circuitry may comprise a direct current-direct current converter arranged to convert an input current from the respective one of the first or second electrodes to a fixed current.

Viewed from a second aspect, there is also provided a method of harvesting energy, the method comprising: disposing a plurality of quantum dot layers in layered formation onto a first electrode; disposing a second electrode onto the plurality of quantum dot layers; generating the emission of electrons from the first electrode to generate tunnelling of the electrons through the plurality of quantum dot layers and into the second electrode; generating the transmission of the electrons from the second electrode to power management circuitry.

Viewed from a third aspect, there is provided an energy harvesting device comprising a first electrode and a second electrode spaced apart relative to each other to define a cavity, a plurality of nanowires disposed within the cavity, wherein each of the nanowires comprises a plurality of quantum dots along the length of the nanowire.

### BRIEF DESCRIPTION OF THE DRAWINGS

FIGS. 1a-1c illustrate a device in accordance with the first embodiment;

FIG. 2 illustrates the energy levels of the sequence of quantum dot layers;

FIGS. 3a-3b illustrate the performance of the device in both the inelastic and elastic conductance;

FIG. 4 illustrates the performance of the device; and

FIG. 5 illustrates a device in accordance with the second embodiment.

### DETAILED DESCRIPTION OF THE INVENTION

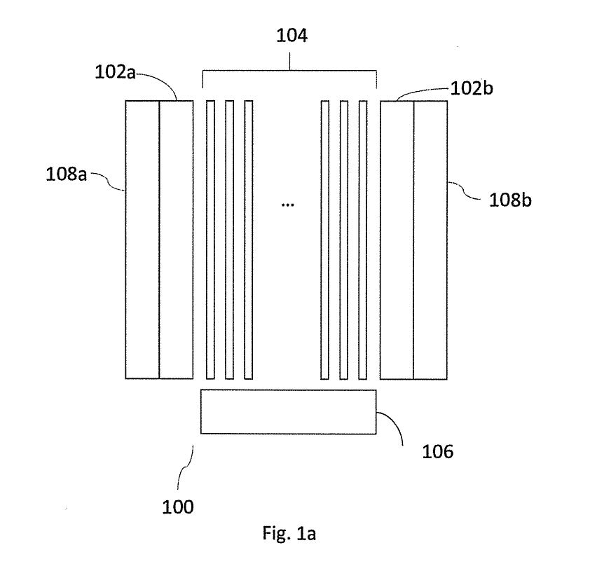

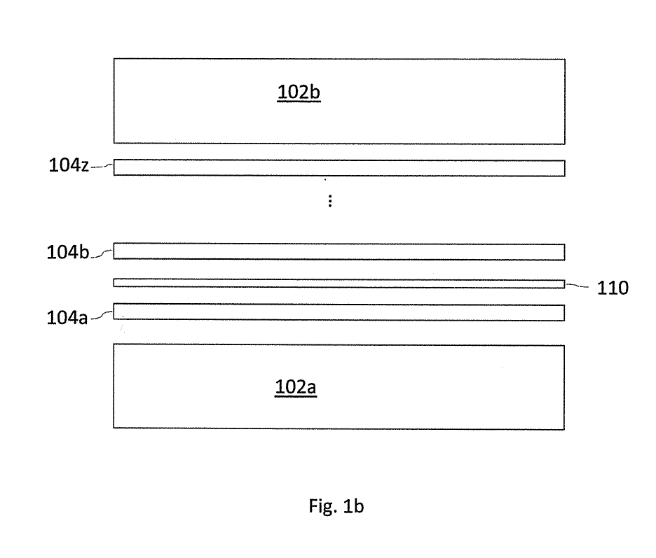

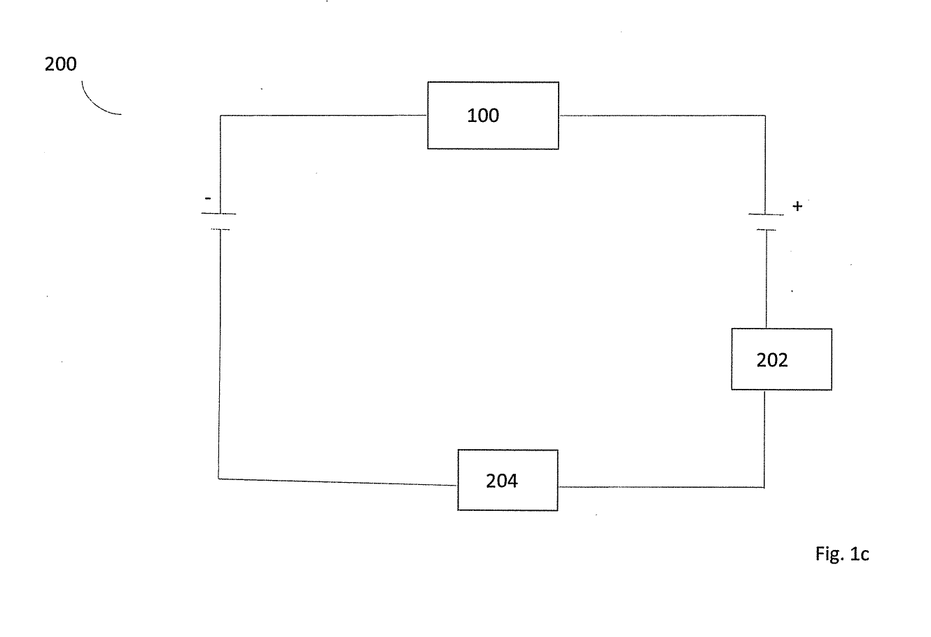

We now describe, with reference to FIG. 1, a device in accordance with the first embodiment.

Device 100 comprises a left electrode 102a and a right electrode 102b and a cavity therebetween. Within the cavity are disposed a plurality of quantum dot layers 104. A radiator 106, i.e. a source of heat, is disposed perpendicularly to the quantum dot layers 104.

The left electrode 102a may be deposited on a first silicon substrate. The right electrode 102b may be deposited on a second silicon substrate.

The source of heat may be any surface which is prone to heating. The surface may form part of device 100 and provide the source of heat to the device. The device 100 may be mounted to such a surface and enable the heat generated by that surface to be used to harvest energy.

The source of heat may also be heat generated from an industrial unit or other device.

Each of the plurality of quantum dot layers comprises a plurality of quantum dots which are uniformly spaced along the respective quantum dot layer 104. Quantum dots are nanoscale devices which tightly confine either electrons or holes in all three spatial dimensions.

The first layer is a silicon layer 108a. A semiconductor substrate is selected as the left electrode 102a. Suitable materials include gold or silver. The semiconductor substrate is then deposited onto the silicon layer using a standard technique. Suitable techniques include physical vapour deposition, chemical vapour deposition, electrochemical deposition, molecular beam epitaxy and atomic layer deposition.

The first quantum dot layer 104a is deposited onto the left electrode 102a by spin coating and then a layer of glue 110 is placed onto the first quantum dot layer 104a before the second quantum dot layer 104b is deposited onto the layer of glue. This is repeated until each of the quantum dot layers are disposed in layered formation onto the left electrode 102a. Although FIG. 1b illustrates quantum dot layers from 104a to 104z, this is only illustrative and the number of quantum dot layers can be configured according to the needs to the device 100 and its application.

The quantum dot layers 104a to 104z may, alternatively, be printed in successive layers over the left electrode 102a using standard printing techniques.

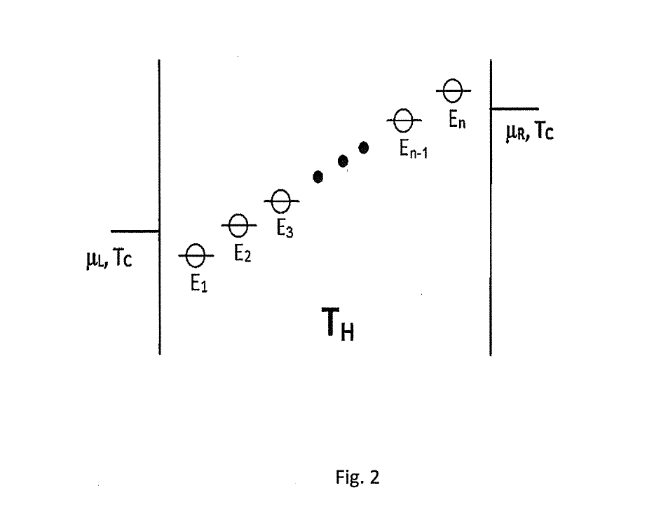

Each of the quantum dot layers 104a to 104z has an energy level which is higher than the previous quantum dot layer. This is illustrated in FIG. 2. In FIG. 2, T_{c} denotes the temperature of the cold region and T_{H} denotes the temperature of the hot region, μ_{L} denotes the electrochemical potential of the first heat sink 108a and μ_{R} denotes the electrochemical potential of the second heat sink 108b.

Implementing quantum dot layers 104 with varying energy levels can be achieved by using quantum dots in each of the quantum dot layers 104 of successively smaller radius. That is to say, the radius of the quantum dots used in quantum dot layer 104b is smaller relative to quantum dot layer 104a by an amount proportional to ΔE, i.e. the difference in energy levels between successive quantum dot layers.

The quantum dot layers 104 can be purchased in colloidal suspension from BBI in Cardiff, UK.

E_{L} is the energy level of the left electrode, E_{N} denotes the energy level of the nth electrode.

A second electrode layer, i.e. right electrode 102b is then deposited over quantum dot layer 104z. Second electrode layer 102b may be identical to the left electrode 102a.

A first heat sink 108a is attached to the left electrode 102a and a second heat sink 108b is attached to the right electrode 102b.

The radiator 106 heats up the left electrode 102a causing it to emit electrons which tunnel into adjacent quantum dots in the quantum dot layer 104a. The presence of radiator 106 introduces phonons into the quantum dot layers 104. The energy of the phonons causes electrons to be scattered by electron-phonon interaction. This increases the energy levels of the scattered electrons in the first quantum dot layer which causes them to tunnel to the second quantum dot layer 104b (when they achieve an energy level of E1) where this process is repeated by the energy of the phonons which is present in the next quantum dot layer, i.e. the electrons scattered inside the first quantum dot layer will be further scattered by the energy of the phonons in the second quantum dot layer 104b which increases the energy level of the scattered electrons to E2. This causes the scattered electrons at energy level E2 to tunnel into the third quantum dot layer 104c and so on and so forth until scattered electrons reach the final quantum dot layer 104z. The phonons interacting with electrons therefore generates an inelastic thermoelectric current flowing from lower energy QDs to higher energy QDs. The electrons in the final quantum dot layer then tunnel into the right electrode 102b.

This process generates an electric potential between the left electrode 102a and the right electrode 102b. This enables the device 100 to be used as part of a battery which could be used to power, say, for example, a mobile computing device, or a sensor.

The electrons which are tunnelled into the right electrode 102b are then conducted through the right electrode 102b into power management circuitry 202 attached to the right electrode 102b. The device 100 and the power management circuitry may form part of a circuit 200 which is used to power a device such as, for example, a mobile telephone 204. This is illustrated in FIG. 1c.

Even a device 100 where the surface area of the respective left and right electrode is only 1 cm×1 cm with a thickness of only 0.05 cm and where the quantum dot layers are only of a thickness of 100 nm can generate 1 mw of electrical power. The dimensions of the electrodes and the quantum dot layers can be configured according to purpose.

We schematically illustrate in FIG. 1c a circuit 200 which uses the energy harvested by energy harvesting device 100.

The PMC 202 comprises power regulation circuitry which uses a direct current (DC) to direct current (DC) converter to convert the voltage from the input level to the level required to power the device 204.

The PMC 202 may be attached to right electrode 102b, i.e. formed integrally with device 100, or may be a discrete component in the circuit 200.

The effect of this is that a battery which converts the heat energy generated by the heat source, i.e. radiator 106, into electrical power which can be used to power device 204.

### Numerical Analysis

We now illustrate using theoretical (hopping theory) and numerical analysis how device 100 can be used to generate large amounts of electrical power.

The investigation of hopping thermoelectric transport has described in many previous literatures. Here for the staircase gradient potential in the high temperature region implemented by a series of connected quantum dots as illustrated in FIG. 2.

The operational principle is based on electrons moving from lower energy dots to higher energy dots assisted by phonon energy which subsequently generates electricity.

The difference of energy levels between the first layer and the nth layer, ΔE can be defined as:

ΔE=E_{N}−E₁

ΔE characterises the energy an electron gains in passing through the cavity between the N quantum dot layers.

The output power of device 100 is in direct relation to the conductance between electrodes, the fundamental analysis should be centred at the solving the equations for the conductance across the quantum dot layers 104.

Assumption is made for each quantum state that only one electron can occupy any quantum dot at any one time. The conductance between dots is assisted by the injected phonons and governed by hopping theory. The electron transition rate between two adjacent dots Eᵢ and Ei+1 (i=0, 1, 2, 3 . . . n) is given by the Fermi golden rule

$${Γ}_{i \to i + 1} = 2 π {\sum }_{q} {\vert {M}_{i , i + 1} \vert}^{2} δ ( {E}_{i + 1} - {E}_{i} - {E}_{p} ) {f}_{i} ( 1 - {f}_{i + 1} ) {N}_{i , i + 1} \qquad ( 1 )$$

where M_{i, i+1} is the electron-phonon interaction matrix element between the two dots having energies Eᵢ and Eᵢ₊₁, which can be expressed as:

Mi, i+1+αₑ₋ₚₕ exp(−|xᵢ₊₁−xᵢ|/ξ)

where αe-ph stands for the electron-phonon coupling energy, ξ is the localization length. Ep is the incident 4 phonon energy, fᵢ and fᵢ₊₁ are the occupation probabilities on the quantum dot i and i+1 respectively, expressed by the Fermi distribution:

Fi=1/[exp(|Eᵢ−μᵢ|/(k_{B}T_{H}))+1].

N_{i, i+1} is the phonon distribution at the energy Eₚ=|Eᵢ₊₁−Eᵢ|, which is determined by the phonon bath expressed by the Bose-Einstein distribution:

Ni, i+1=1/[exp(|Eᵢ₊₁−Eᵢ|/(k_{B}T_{H}))−1].

The Fermi golden rule can be written in a shorter form assuming the overlap of the wave functions of two quantum dots is small, which is:

Γ_{i→i+1}=γₑₚfᵢ(1−fᵢ₊₁)N_{i,i+1}

γₑₚ=2π|M_{i,i+1}|²ρₚₕ(|E_{i,i+1}|)=2π|αₑ₋ₚₕ|²exp(−2x_{i,i+1}/ξ)ρₚₕ(|E_{i,i+1}|)

where x_{i,i+1}=|xᵢ₊₁−xᵢ| is the physical distance between quantum dot i and quantum dot i+1, and ρₚₕ(|E_{i,i+1}|) is the density of states.

The tunnelling from the dot E_{L} to the left electrode can be accomplished by elastic tunnelling processes with a transition rate of:

Γ_{L→1}=γ_{L,1fl}(1−f₁)

where:

ΓL,₁=2π|J_{L,1}|²ρ₁(E₁),

J_{L,1} is the coupling between dot 1 and the left lead and

J_{L,1}˜exp(−|x_{L}−x₁|/ξ)

and f₁ is the Fermi distribution of the dot 1;
ρ₁(E₁) denotes the density of the states to the left lead and fL is the Fermi distribution of the left lead:

$${f}_{l} = {[ 1 + exp ( \frac{{E}_{L} - {μ}_{L}}{{k}_{B} {T}_{C}} ) ]}^{- 1} .$$

The transition rate from the dot E_{N} to the right lead is expressed similarly to Γ_{L→1}.

Under the assumption that the overlap of wave functions of the two adjacent dots is exponentially small, that is |xᵢ₊₁−xᵢ|>>ξ, the linear hopping conductance between two adjacent energy states can be expressed as:

$${G}_{i , i + 1} ≅ {G}_{01} exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} ) \qquad ( 3 )$$

where μ₀ is the electrochemical potential of the cavity between the left electrode 102a and the right electrode 102b. As ΔE is uniform across the staircase energy levels, we can assume that the energy levels of the left and right quantum dots are symmetric around the μ₀ and μ₀=0.

The conductance between E₁ to the left lead is dominated by elastic tunnelling as the localisation length is smaller than the distance between the quantum dot layers 104:

$${G}_{L} ≅ {G}_{02} exp ( - \frac{2 {x}_{L , 1}}{ξ} - \frac{\vert {E}_{L} - {μ}_{L} \vert}{2 {k}_{B} {T}_{C}} )$$

$${G}_{R} ≅ {G}_{03} exp ( - \frac{2 {x}_{N , R}}{ξ} - \frac{\vert {E}_{R} - {μ}_{R} \vert}{2 {k}_{B} {T}_{C}} )$$

where:

$${G}_{01} ∼ \frac{{e}^{2}}{{k}_{B} T} {\vert {α}_{e - ph} \vert}^{2} {ρ}_{ph} ( \vert {E}_{i , i + 1} \vert )$$

$${G}_{02} ∼ \frac{{e}^{2}}{{k}_{B} T} {\vert {α}_{e} \vert}^{2} {ρ}_{L} ( \vert {E}_{L} \vert )$$

$${G}_{03} ∼ \frac{{e}^{2}}{{k}_{B} T} {\vert {α}_{e} \vert}^{2} {ρ}_{R} ( \vert {E}_{R} \vert ) .$$

We can then express the total conductance Gₜ between dots E_{L} and E_{R} is:

$$\frac{1}{{G}_{t}} = \frac{1}{{G}_{01}} {\sum }_{i = 1}^{n - 1} \frac{1}{exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )} + \frac{2}{{G}_{01} exp ( - \frac{2 {x}_{L , 1}}{ξ} - \frac{\vert {E}_{L} - {μ}_{L} \vert + \vert {E}_{1} - {μ}_{1} \vert + \vert {E}_{1} - {E}_{L} \vert}{2 {k}_{B} {T}_{H}} )}$$

If we assume that a single hopping can take place between EL and ER without any intervening quantum dot layers 104 but rather a standard conducting material with an electrochemical potential of μ₀, the conductance Gₛ₋ₕ

$${G}_{s - h} ≅ {G}_{01} exp ( - \frac{2 W}{ξ} - \frac{\vert {E}_{L} - {μ}_{0} \vert + \vert {E}_{R} - {μ}_{0} \vert + \vert {E}_{R} - {E}_{L} \vert}{2 {k}_{B} {T}_{H}} )$$

using:

$${G}_{i , i + 1} ≅ {G}_{01} exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )$$

We can calculate the linear transport of the device with staircase energy states across the plurality of quantum dot layers across the cavity between left electrode 102a and right electrode 102b.

Given the total conductance Gₜ calculated according to hopping theory as set out above, i.e.

$$\frac{1}{{G}_{t}} = \frac{1}{{G}_{01}} {\sum }_{i = 1}^{n - 1} \frac{1}{exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )} + \frac{2}{{G}_{01} exp ( - \frac{2 {x}_{L , 1}}{ξ} - \frac{\vert {E}_{L} - {μ}_{L} \vert + \vert {E}_{1} - {μ}_{1} \vert + \vert {E}_{1} - {E}_{L} \vert}{2 {k}_{B} {T}_{H}} )}$$

We can use the Onsager reciprocity relations for a three-terminal thermoelectric system, the electrical current Iₑ, energy current I_{Q}^{e} and the heat current I_{Q}^{pe} exchanged between the electrons and the phonons can be expressed as functions of three external “forces” given as:

δμ=μ_{L}−μ_{R}, δT=T_{L}−T_{R}, ΔT=T_{H}−T_{C}

For an electron transferred from left to right, the heat bath gives out energy −E_{L} to the left lead and E_{R} to the right lead and the phonons transfer the energy ΔE=E_{R}−E_{L} to electrons.

The central hot region has temperature of T_{H}, and cold regions (left and right leads) have the temperature TC. A net energy of E=(EL+ER)/2 is transferred from left to right. The linear transport satisfying the Onsager reciprocity relations is:

$$( \begin{matrix}{I}_{e} \\ {I}_{Q}^{e} \\ {I}_{Q}^{pe}\end{matrix} ) = ( \begin{matrix}{L}_{31} & {L}_{12} & {L}_{13} \\ {L}_{21} & {L}_{22} & {L}_{23} \\ {L}_{31} & {L}_{32} & {L}_{33}\end{matrix} ) ( \begin{matrix}δ μ \\ δ T \\ Δ T\end{matrix} )$$

where:

$${L}_{11} = \frac{G}{e}$$

$${L}_{12} = {L}_{21} = \frac{G}{e} \frac{1}{{T}_{C}} \overline{E}$$

$${L}_{13} = {L}_{31} = \frac{G}{e} \frac{1}{{T}_{C}} Δ E$$

$${L}_{22} = \frac{G}{e} \frac{1}{{T}_{C}} \frac{\overline{E}}{e} \overline{E}$$

$${L}_{23} = {L}_{32} = \frac{G}{e} \frac{1}{{T}_{C}} \frac{Δ E}{e} \overline{E}$$

$${L}_{33} = \frac{G}{e} \frac{1}{{T}_{C}} \frac{Δ E}{e} Δ E$$

The meaning of the Onsager matrix is that every transport process affects all other processes and the diagonal terms of the Onsager matrix connects each generalised force with its conjugated current.

The off-diagonal tefins determine the influence of each force on the non-conjugate currents.

G can be determined by the following equations:

$${G}_{L} ≅ {G}_{02} exp ( - \frac{2 {x}_{L , 1}}{ξ} - \frac{\vert {E}_{L} - {μ}_{L} \vert}{2 {k}_{B} {T}_{C}} )$$

$${G}_{R} ≅ {G}_{03} exp ( - \frac{2 {x}_{N , R}}{ξ} - \frac{\vert {E}_{R} - {μ}_{R} \vert}{2 {k}_{B} {T}_{C}} )$$

$$\frac{1}{{G}_{t}} = \frac{1}{{G}_{01}} {\sum }_{i = 1}^{n - 1} \frac{1}{exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )} + \frac{2}{{G}_{01} exp ( - \frac{2 {x}_{L , 1}}{ξ} - \frac{\vert {E}_{L} - {μ}_{L} \vert + \vert {E}_{1} - {μ}_{1} \vert + \vert {E}_{1} - {E}_{L} \vert}{2 {k}_{B} {T}_{H}} )}$$

The thermopower Sₚ of the above three-terminal system is:

$${S}_{p} = \frac{{L}_{13}}{G} = \frac{Δ E}{e {T}_{C}}$$

That is to say, the thermopower of the three terminal system modelled above is directly proportional to ΔE, i.e. the thermopower of a device which uses staircase energy levels in the cavity between the left electrode 102a and the right electrode 102b is directly proportional to ΔE.

The power factor P can be calculated using the thermopower Sₚ and the total electrical conductivity of the quantum dot layers 104a as:

P=GSₚ²

That is to say, power is proportional to both thermopower and the total electrical conductivity. The performance of the three-terminal device can be expressed as:

$$ZT = \frac{{L}_{13}^{2}}{( {GL}_{33} / {T}_{C} - {L}_{13}^{2} )}$$

ZT approximates to infinity ideally but becomes finite when the electron transmission through the quantum dot layers 104 is elastic.

If the hopping conductance across the cavity is optimized then we can analyze the elastic tunnelling current between the left and right leads and the left-most and right-most quantum energy level, I_{L,R} denotes the electrical current in the left and right leads.

The electrical currents I_{L,R} is given by:

I_{L}=(2e/h)∫dET_{L}(E)[f_{L}−f_{QL}]

I_{R}=(2e/h)∫dET_{R}(E)[f_{R}−f_{QR}]
where T_{L,R}(E) is the transmission function of each contact for each incident electron energy E, which takes Lorentzian shape:

$${T}_{L} ( E ) = \frac{{Γ}_{1} {Γ}_{2}}{{( E - {E}_{L} )}^{2} + {( \frac{{Γ}_{1} + {Γ}_{2}}{2} )}^{2}}$$

where Γ₁ and Γ₂ are the attempt frequencies of the two barriers of the resonant quantum dots. If we assume symmetric coupling between quantum dot layers, so that Γ₁=Γ₂=w, where w is the width of the energy level.

We now numerically study the optimized number of quantum dot layers required to achieve maximum conductance and the elastic tunnelling between the leads and the dots.

If we set:
w=1000 nm;
G₀₁=10000 (a.u);
E_{L}=−20 (a.u);
E_{R}=20 (a.u); and
k_{B}T_{H}=1.

The total conductance for a two-dot system and a multi-dot system can be calculated using equations (5) and (6) where:

$$exp ( - \frac{2 {x}_{i , i + 1}}{ξ} ) , \\ exp ( - \frac{2 {x}_{L , 1}}{ξ} ) , and$$

$$exp ( - \frac{2 W}{ξ} )$$

are negligible as |xi+1−xi)>>ξ.

Making this assumption about the asymptotics of these quantities enables us to simplify the equation:

$$\frac{1}{{G}_{t}} = \frac{1}{{G}_{01}} {\sum }_{i = 1}^{n - 1} \frac{1}{exp ( - \frac{2 {x}_{i , i + 1}}{ξ} - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )} + \frac{2}{{G}_{01} exp ( - \frac{2 {x}_{L , 1}}{ξ} - \frac{\vert {E}_{L} - {μ}_{L} \vert + \vert {E}_{1} - {μ}_{1} \vert + \vert {E}_{1} - {E}_{L} \vert}{2 {k}_{B} {T}_{H}} )}$$

Such that it becomes:

$${( \frac{1}{{G}_{01}} {\sum }_{i = 1}^{n} \frac{1}{exp ( - \frac{\vert {E}_{i} - {μ}_{i} \vert + \vert {E}_{i + 1} - {μ}_{i + 1} \vert + \vert {E}_{i + 1} - {E}_{i} \vert}{2 {k}_{B} {T}_{H}} )} )}^{- 1}$$

If we make the assumption that only a single electron is allowed in the quantum dot, i.e.

|Eᵢ−μᵢ|=0

|Eᵢ₊₁−μᵢ₊₁|=0

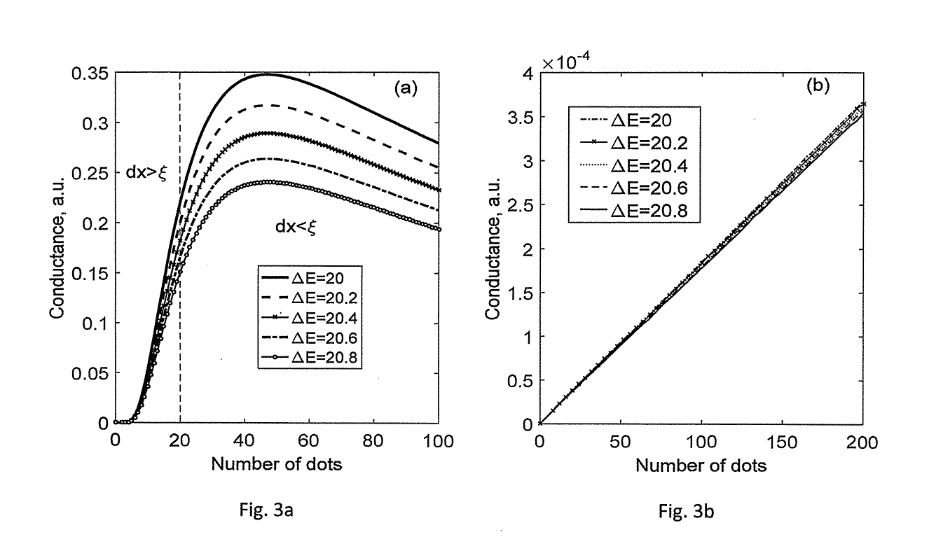

If we let the number of quantum dots N vary between 3 and 200 we can observe the results in FIG. 3 where it is shown that the optimised number of dots is 60.

FIG. 3a shows the results of the simulated conductance with W=20 (a.u), and ΔE ranging from 20 to 20.8 using hopping theory. The number of dots ranged from 2 to 100 and an optimal value for the number of dots is observed at 60.

FIG. 3b shows the results of the simulated conductance using the Landaeur integral to calculate the elastic current. The calculated current is calculated using I/V, i.e. the quotient between current and voltage. We again set W at 20.

All of the dots were modelled as resistors connected in parallel with μ_{L,R}=+/−(ΔE/2)*0.6.

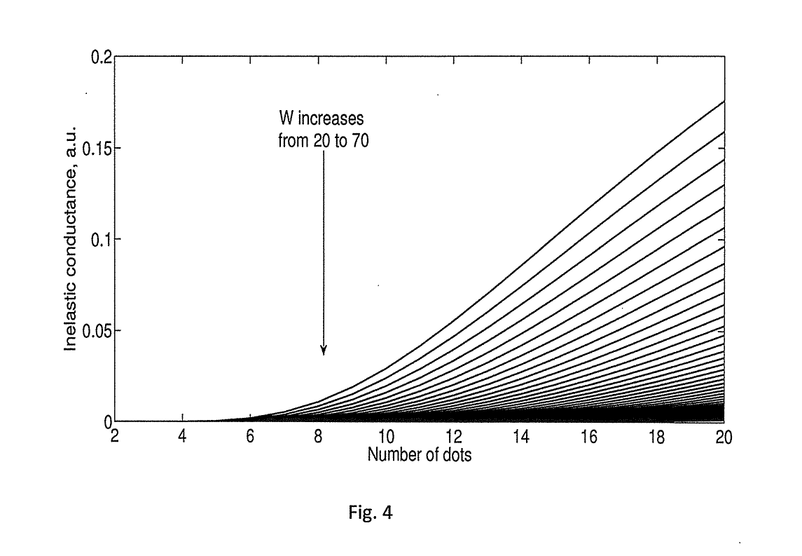

FIG. 4 illustrates the calculated inelastic conductance with a varying cavity width. In the simulation W=20−70, ΔE=20 to 70 and the number of dots ranges from 2 to 20. FIG. 4 shows that the ratio of the optimised number of dots relative to the ΔE is a constant 0.5.

If we use a staircase energy level across the quantum dot layers 104, we also need to investigate the elastic tunnelling current between the two leads and the left and right electrodes E_{L} and E_{R} using the equations below:

$${I}_{L} = ( 2 e / h ) \int {dET}_{L} ( E ) [ {f}_{L} - {f}_{QL} ]$$

$${I}_{R} = ( 2 e / h ) \int {dET}_{R} ( E ) [ {f}_{R} - {f}_{QR} ]$$

$${T}_{L} ( E ) = \frac{{Γ}_{1} {Γ}_{2}}{{( E - {E}_{L} )}^{2} + {( \frac{{Γ}_{1} + {Γ}_{2}}{2} )}^{2}}$$

We set ΔE=40 and the second dot from the left E₁ and the second dot from the right E_{N} varies from δE=E_{N}−E₁=0 to 0.9*ΔE and w=k_{B}T and numerically evaluated the integral for I_{L} and I_{R}. This illustrates that maximum power output is when the series of staircase energy states matches with the energy levels on E_{L} and E_{R}.

It is shown that thermoelectric energy harvesters have been developed which have very high conversion efficiency by implementing quantum dots/wells between the high temperature region and the low temperature region forming three-terminal inelastic thermoelectric transportation.

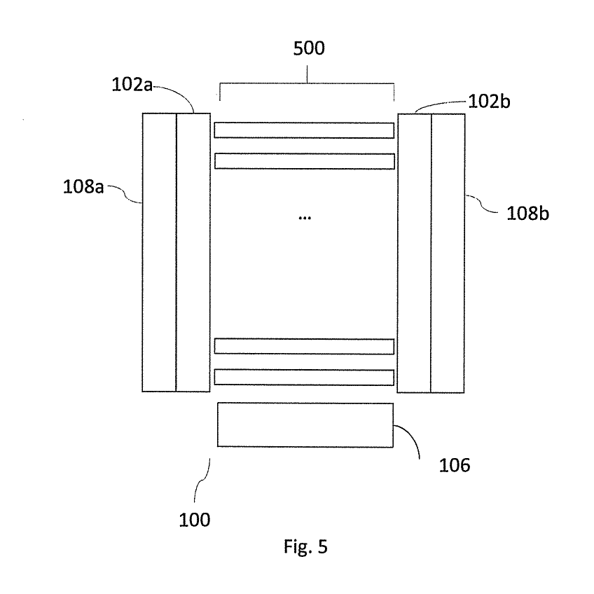

We now illustrate with reference to FIG. 5, a device 100 according to a second embodiment which can be used to convert themial energy into electrical power.

Device 100 comprises a left electrode 102a and a right electrode 102b and a cavity therebetween. A plurality of nanowires 500 with quantum dots disposed along their length may be grown onto the left electrode 102a using the technique described in [1].

A radiator 106, i.e. a source of heat, is disposed perpendicularly to the quantum dot layers 104.

The left electrode 102a may be deposited on a first silicon substrate. The right electrode 102b may be deposited on a second silicon substrate.

The source of heat may be any surface which is prone to heating. The surface may form part of device 100 and provide the source of heat to the device. The device 100 may be mounted to such a surface and enable the heat generated by that surface to be used to harvest energy. The source of heat may also be heat generated from an industrial unit or other device.

A semiconductor substrate is selected as the left electrode 102a. Suitable materials include gold or silver. The semiconductor substrate is then deposited onto the silicon layer using a standard technique. Suitable techniques include physical vapour deposition, chemical vapour deposition, electrochemical deposition, molecular beam epitaxy and atomic layer deposition.

Each of the quantum dots along the length of one of the nanowires has an energy level which is higher than the previous quantum dot. The energy level of a respective quantum dot is inversely proportional to its radius.

E_{L} is the energy level of the left electrode, E_{N} denotes the energy level of the right electrode.

A second electrode layer, i.e. right electrode 102b is then deposited over the plurality of nanowires. Second electrode layer 102b may be identical to the left electrode 102a.

A first heat sink 108a is attached to the left electrode 102a and a second heat sink 108b is attached to the right electrode 102b.

The radiator 106 heats up the left electrode 102a causing it to emit electrons which tunnel into adjacent quantum dots in a respective nanowire. The presence of radiator 106 introduces phonons into the quantum dots. The energy of the phonons causes electrons to be scattered by electron-phonon interaction. This increases the energy levels of the scattered electrons in the first quantum dot along the length of a nanowire which causes the scattered electron to tunnel to the second quantum dot (when they achieve an energy level of E1) where this process is repeated by the energy of the phonons which is present in the next quantum dot layer, i.e. the electrons scattered inside the first quantum dot will be further scattered by the energy of the phonons in the second quantum dot which increases the energy level of the scattered electrons to E2. This causes the scattered electrons at energy level E2 to tunnel into the third quantum dot and so on and so forth until scattered electrons reach the final quantum dot. The phonons interacting with electrons therefore generates an inelastic thermoelectric current flowing from lower energy QDs to higher energy QDs. The electrons in the final quantum dot then tunnel into the right electrode 102b.

This process generates an electric potential between the left electrode 102a and the right electrode 102b. This enables the device 100 to be used as part of a battery which could be used to power, say, for example, a mobile computing device, or a sensor.

The electrons which are tunnelled into the right electrode 102b are then conducted through the right electrode 102b into power management circuitry 202 attached to the right electrode 102b. The device 100 and the power management circuitry may form part of a circuit 200 which is used to power a device such as, for example, a mobile telephone 204.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. In the present specification, “comprises” means “includes or consists of” and “comprising” means “including or consisting of”. The singular reference of an element does not exclude the plural reference of such elements and vice-versa.

### REFERENCES

[1] Tatebayashi et al “Room-temperature lasing in a single nanowire with quantum dots” Nature Photonics, Vol. 9, August 2015

1. An energy harvesting device comprising:
a first electrode and a second electrode spaced apart relative to each other to define a cavity; and
a plurality of quantum dot layers disposed within the cavity to generate an electrical potential between the first and second electrodes.

2. The energy harvesting device according to claim 1, wherein each of the plurality of quantum dot layers has an energy level which is higher than the energy level of the preceding quantum dot layer.

3. The energy harvesting device according to claim 1, wherein each of the quantum dot layers comprises a plurality of quantum dots uniformly distributed in a colloidal substance.

4. The energy harvesting device according to claim 1, wherein the number of quantum dot layers is between 20 and 40.

5. The energy harvesting device according to claim 3, wherein the radius of the quantum dot is inversely proportional to the energy level of the quantum dot.

6. The energy harvesting device according to claim 1, wherein the spacing between the quantum dot layers is less than a localisation length of the quantum dot layer.

7. The energy harvesting device according to claim 1, wherein power management circuitry is coupled to one of the first or second electrodes.

8. The energy harvesting device according to claim 1, wherein a heat source is coupled to the device to generate the emission of electrons from one of the first or second electrodes.

9. The energy harvesting device according to claim 7, wherein the power management circuitry comprises a direct current-direct current converter arranged to convert an input current from the respective one of the first or second electrodes to a fixed current.

10. A battery comprising:
a device in accordance with claim 1.

11. A battery comprising:
a plurality of devices in accordance with claim 1.

12. A sensor arrangement comprising a battery in accordance with claim 10.

13. A sensor arrangement comprising a battery in accordance with claim 11.

14. A mobile computing device comprising a battery in accordance with claim 10.

15. A mobile computing device comprising a battery in accordance with claim 11.

16. A method of harvesting energy, the method comprising:
disposing a plurality of quantum dot layers in layered formation onto a first electrode;
disposing a second electrode onto the plurality of quantum dot layers;
generating the emission of electrons from the first electrode to generate tunnelling of the electrons through the plurality of quantum dot layers and into the second electrode;
generating the transmission of the electrons from the second electrode to power management circuitry.

17. An energy harvesting device comprising:
a first electrode and a second electrode spaced apart relative to each other to define a cavity; and
a plurality of nanowires disposed within the cavity, wherein each of the nanowires comprises a plurality of quantum dots along the length of the nanowire to generate an electrical potential between the first and second electrodes.

18. The device according to claim 17, wherein each of the plurality of quantum dots is of an energy level which is higher than the preceding quantum dot.

19. The device according to claim 17, wherein the radius of the quantum dot is inversely proportional to the energy level of the respective quantum dot.
